(19) United States
(12) Patent Application Publication
(10) Pub. No.: US 2004/0011286 A1
(43) Pub. Date: Jan. 22, 2004

(54) Batch type atomic layer deposition apparatus and in-situ cleaning method thereof

(75) Inventor: Hyug-Jin Kwon, Kyoungki-Do (KR)

Correspondence Address: MARSHALL, GERSTEIN & BORUN LLP, 6300 SEARS TOWER, 233 S. WACKER DRIVE, CHICAGO, IL, 60606, US

(73) Assignee: HYNIX SEMICONDUCTOR INC., Kyoungki-Do (KR)

(21) Appl. No.: 10/615,062

(22) Filed: Jul. 8, 2003

(30) Foreign Application Priority Data
Jul. 19, 2002 (KR) 2002-42297

(51) Int. Cl. C23C 16/00

(52) U.S. Cl. 118/715

(57) ABSTRACT

The present invention provides a batch type atomic layer deposition. Particularly, the batch type ALD apparatus and an in-situ cleaning method thereof supplies a cleaning gas to a central region of an upper plate in a radial form, thereby improving an efficiency on the in-situ cleaning of the batch type ALD apparatus.

### FIELD OF THE INVENTION

The present invention relates to an atomic layer deposition (ALD) apparatus; and more particularly, to a batch type ALD apparatus and an in-situ cleaning method thereof.

### DESCRIPTION OF THE PRIOR ART

Recently, an atomic layer deposition (ALD) technique using a surface reaction is applied to a structure having a high aspect ratio due to a limitation of a chemical vapor deposition (CVD) technique to overcome high aspect ratio.

FIG. 1 is a schematic diagram showing an apparatus for an atomic layer deposition adopting a traveling wave method in accordance with a prior art.

As shown in FIG. 1, the apparatus includes: a chamber 10 using the traveling wave method and having a channel-like shape; a wafer 11 is loaded on a bottom of the chamber 10; first and second channels 12A and 12B for injecting a source gas, a reaction gas and a purge gas being formed on one side of the chamber 10; and a pump for exhausting the gases being equipped on other side of the chamber 10 even if not illustrated.

In performing the atomic layer deposition adopting the traveling wave method, a series of the following processing steps are proceeded; the wafer 11 is loaded into the chamber 10; a process for a chemical absorption of a source gas is carried out on the wafer 11; the remnant source gas is exhausted by injecting a purge gas like an inert gas; an atomic layer is deposited by injecting a reaction gas and subsequently inducing a surface reaction between the chemically absorbed source gas on the wafer and the reaction gas; and the above inert gas is injected again in order to exhaust the remnant gas and. a by-product produced by the surface reaction.

The above series of the processing steps constitute one cycle, and this cycle is repeatedly carried out until obtaining an intended thickness of the atomic layer.

According to the prior art, it is possible to obtain a conformal and uniform film. It is also possible to suppress more effectively a particle generation elicited by a gas phase reaction compared to a CVD technique because the source gas and the reaction gas are separated from each other by the inert gas and then, the separated source/reaction gases are supplied into the chamber 10. In addition, induction of multi-collision between the source gas and the wafer improves efficiency on use of the source gas and reduces a cycle duration period.

However, the above-mentioned prior art of which throughput ranges between about 3 wafer per hour (WPH) and about 4 WPH is not suitable for applying it to a mass production system because lots of equipment, an huge space, and a maintenance expense are needed to maintain such system and the above mentioned throughput is not relatively remarkable.

The Korean patent application No. 10-2002-27614 discloses a batch type atomic layer deposition to overcome the above problems (refer to FIG. 2).

As shown in FIG. 2, the batch type atomic layer deposition apparatus consists of the following parts: a reaction chamber 30 including a sidewall 31C, an upper plate 31A, and a lower plate 31B; a hole type shower head 33 for injecting a source gas, a reaction gas, and a purge gas including a cleaning gas by passing through a channeled central region of the upper plate 31A; a heating plate 33 being attached to the lower plate 31B and being able to control a temperature of any area on a wafer; a rotating axis 34 penetrating through the lower plate 31B and a central region of the heating plate 33; a rotating plate 35 on which a plurality of wafers are loaded with an identical distance from its center and of witch bottom side is fixed to the rotating axis 34; and a baffle structured exhaust 37 which exhausts the gases injected from the hole-type shower head 32 by passing through the lower plate 31B along the sidewall 31C adjacent to an edge area of the rotating plate 35. A groove 35A used for loading the wafer is formed on a surface of the rotating plate 35, wherein the groove prevents an atomic layer from being deposited on a bottom side of the wafer and tightens the wafer so as not to be shaken during the rotation. Herein, TiCl₄, NH₃, Ar and Cl₂ are used as a source gas, a reaction gas, a purge gas and a cleaning gas, respectively.

In addition, the heating plate 33 is divided into three heating zones, that is, Z₁, Z₂ and Z₃ on which wafers are symmetrically loaded around the central region of the heating plate 33. Each of the heating zones has a ring type arc lamp 33A arranged with a constant distance.

More specifically, the heating plate 33 is located right under the rotating plate 35, a first heating zone (Z₁) most closely adjacent to the shower head 32 among the three heating zones has three arc lamps 33A, a third heating zone (Z₃) most closely adjacent to the rotating plate 35 has one arc lamp, and the second heating zone Z₂ existing between the first heating zone Z₁ and the third heating zone Z₃ has two arc lamps 33A.

The batch type atomic layer deposition apparatus shown in FIG. 2 has some advantages in terms of an atomic layer deposition rate and uniformity. In case of reducing the cycle period, a process throughput of a TiN layer deposition increases by about 12 WPH.

A process for cleaning an inside surface of the reaction chamber is carried out after the TiN deposition is performed by using the atomic layer deposition apparatus. In more detail, the cleaning of the inside surface of the reaction chamber, namely in-situ cleaning, is proceeded from a center hole of the shower head 32 by using a gas supplier which rapidly inject Cl₂ gas supplied through a TiCl₄ gas line 32A. This in-situ cleaning of the batch type atomic layer deposition apparatus impedes an underside of the loaded wafer from being deposited with the TiN layer and prevent a particle generation within the groove 35A, commonly named as susceptor, for tightening the loaded wafer. Therefore, the in-situ cleaning process is a requisite, of the atomic layer deposition apparatus for a mass production.

FIG. 3A shows an in-situ cleaning method in accordance with the prior art.

Referring to FIG. 3A, Cl₂/Ar gas continuously flows into a central area of the reaction chamber through the hole type shower head 32 from a first and a second gas line 32A and 32B. At this time, a flow quantity of each Cl₂ and Ar gas is about 800 sccm. Furthermore, the Cl₂ gas is more densely distributed around a center area of a body of the Cl₂ gas and cleans the TiN layer deposited on the rotating plate 35 and the susceptor 35A by thermally dissolving it while the Cl₂ gas spreads out in an radial form. Another gas line is prepared for forcing Ar gas to flow along an underside surface of the rotating plate 45. The flowing Ar gas prevents the deposition from being taken place at the underside surface.

As shown in FIG. 3B, a peripheral area of the rotating plate 35 and the susceptor 35A is easily cleaned while the in-situ cleaning is carried out, however a TiN layer deposited on the center area of the rotating plate is not easily cleaned because the deposited TiN layer has a topologically different thickness. Also, a ring pattern formed on the deposited TiN layer due to the topologically different thickness still remains during the in-situ cleaning process.

According to an X-ray examination of the remnant layer having the ring pattern, there is no peak of any other crystal structure as well as Tin crystal structure. From this, it is known that the deposited TiN layer may have an amorphous structure.

Actually, a reaction between the TiN layer and Cl₂ gas should be elicited and the TiN layer should be dissolved into by-products of the reaction, that is, TiCl₄ and N₂. Thereafter, the by-products should be detached and pumped out. However, as a matter of a fact, a bamboo or tall grass type by-product is formed and remains on the central area of the rotating plate 35.

The ring pattern is not removed even though the rotating plate 35 is heated to about 450□ and ALD process parameters such as an amount of TiCl₄/Ar/NH₃ gas, a cycle period, and a distance between the rotating plate 35 and the upper plate 31A are adjusted. Actually, these treatments remove a partial portion of the ring pattern, not the whole pattern.

There are several factors causing this technical problem. First of all, the Cl₂ gas is supplied only to the central area of the rotating plate, and the excessive Cl₂ gas supply to the central area prevents the generated by-products from being detached. As a result, the by-products are re-deposited. Compared with a shower head type apparatus supplying gas uniformly on an entire surface of a wafer, the batch type atomic layer deposition apparatus supplies all gases from the central area of the upper plate.

Therefore, a level of impurities, usually metal elements formed on the central area of the loaded wafer, is higher than on other areas. Consequently, the generated by-products are not easily removed even though there occurs the reaction between the Cl₂ gas and the by-products.

### SUMMARY OF THE INVENTION

It is, therefore, an object of the present invention to provide a batch type atomic layer deposition (ALD) apparatus capable of improving a cleaning efficiency by supplying a cleaning gas to a central area of an upper plate in an radial form and an in-situ cleaning method thereof.

In accordance with an aspect of the present invention, there is provided the batch type atomic layer deposition apparatus, including: a reaction chamber having a predetermined volume constituted with an upper plate, a lower plate and sidewalls; a rotating plate loaded with a plurality of wafers, wherein each wafer is located in the reaction chamber and loaded radially at a predetermined position disposed in an identical distance from a center of the rotating plate; a radial shower head for forcing a gas to flow toward an upper surface of the wafer as passing through a center of the upper plate, wherein the radial shower head faces a center of an upper surface of the rotating plate; a heating plate having a heating zone capable of controlling a temperature of any area and being located on the lower plate with a predetermined distance of the rotating plate; a cooling plate attached to an upper surface of the upper plate; and a plasma excitement electrode encompassing an entrance of the radial shower head by being located between the cooling plate and the entrance of the radial shower head.

### BRIEF DESCRIPTION OF THE DRAWINGS

The above and other objects and features of the instant invention will become apparent from the following description of preferred embodiments taken in conjunction with the accompanying drawings, in which:

FIG. 1 is a schematic diagram showing an atomic layer deposition adopting a traveling wave method according to a prior art;

FIG. 2 is a schematic diagram showing a batch type atomic layer deposition apparatus according to a prior art;

FIG. 3A is a diagram illustrating an in-situ cleaning method using the batch type atomic layer deposition apparatus shown in FIG. 2;

FIG. 3B is a diagram showing a result of the in-situ cleaning according to the in-situ cleaning method shown in FIG. 3A;

FIG. 4 is a diagram showing a structure of a batch type atomic layer deposition apparatus in accordance with an first preferred embodiment of the present invention;

FIG. 5 is a diagram showing a structure of a batch type atomic layer deposition apparatus in accordance with a second preferred embodiment of the present invention;

FIG. 6 is a diagram illustrating an in-situ cleaning method of the batch type atomic layer deposition apparatus shown in FIG. 4; and

FIG. 7 is a diagram illustrating an in-situ cleaning method of the batch type atomic layer deposition apparatus shown in FIG. 5.

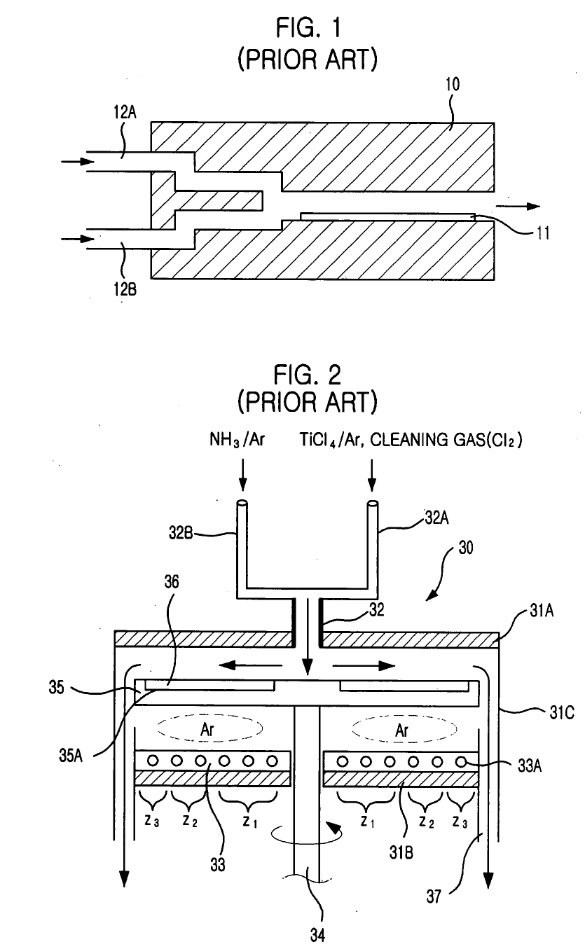

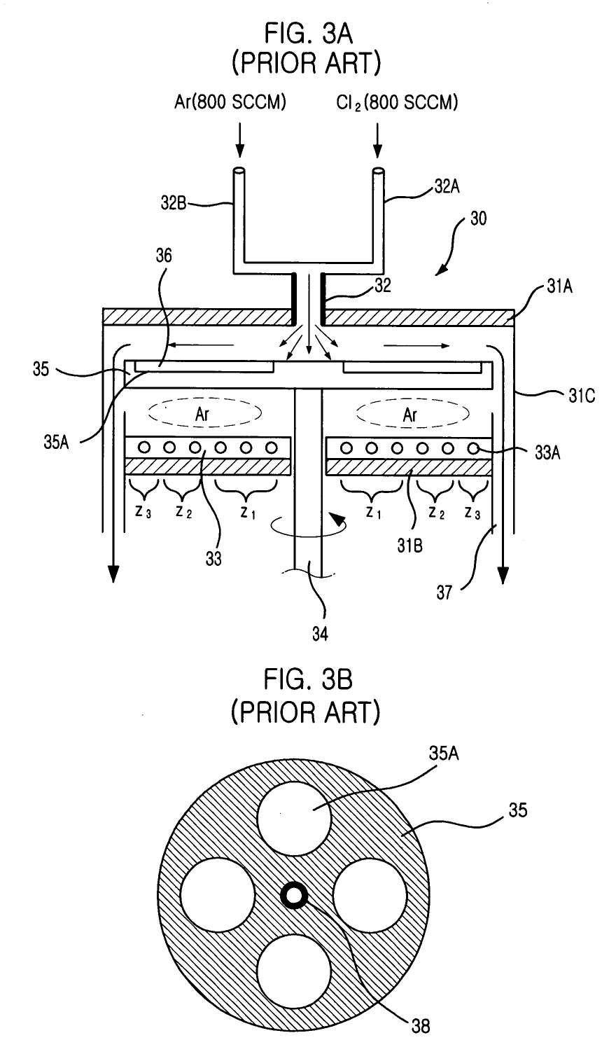

### DETAILED DESCRIPTION OF THE PREFERRED EMBODIMENTS

Hereinafter, a batch type atomic layer deposition (ALD) apparatus in accordance with the present invention will be described in detail referring to the accompanying drawings.

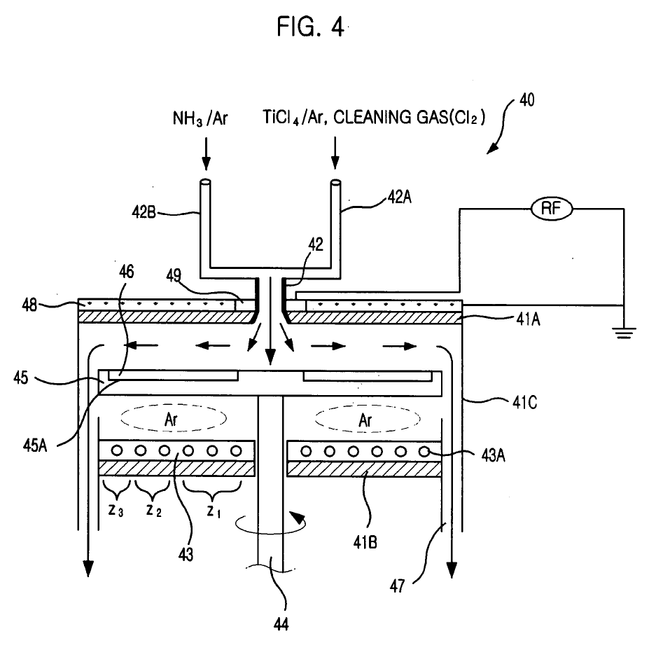

FIG. 4 is a diagram showing a structure of a batch type atomic layer deposition (ALD) apparatus according an embodiment of the present invention.

Referring to FIG. 4, the batch type ALD apparatus includes: a reaction chamber 40 containing sidewalls 41C, an upper plate 41A, and a lower plate 41B; a radial shower head 42 penetrating a center area of the upper plate 41A of the reaction chamber 40 and radially injecting a source gas, a reaction gas, a purge gas, wherein the gases are supplied through a first and a second gas injection line 42A and. 42B; a heating plate 43 attached to the lower plate 41B; a rotating axis 44 penetrating a center of the lower plate 41B and the heating plate 43 simultaneously; a rotating plate 45 on which a plurality of wafers 46 are loaded in an radial form with an identical distance from a center of the rotating plate 45, wherein a center of bottom surface of the rotating plate 45 is fixed at the rotating axis 44; a baffle structured exhaust 47 for exhausting the gases injected from the radial shower head 42, wherein the, exhaust penetrates the heating plate 43 and the lower plate 41b along the sidewall most closely adjacent to an edge area of the rotating plate 45; a cooling plate 48 attached to the upper plate 41A; and a plasma excitement electrode 49 having a ring shape and encompassing an entrance of the radial shower head by being located between the cooling plate 48 and the entrance of the radial shower head 42. Herein, the plasma excitement electrode 49 is supplied with a radio frequency (RF) power. Also, the plasma excitement electrode 49 excites Cl₂/Ar cleaning gas to plasma and forms a Cl₂ radical. Consequently, a reaction between the Cl₂ radical containing activated molecules and a deposited TiN layer is expedited.

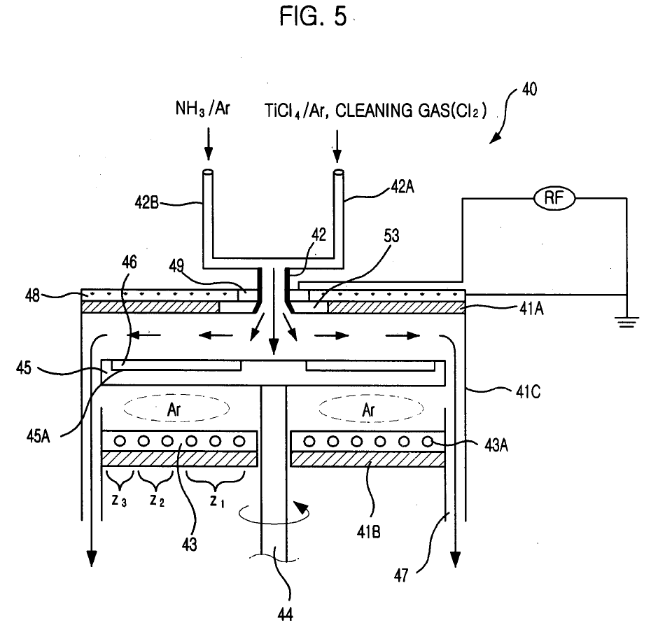

FIG. 5 is a diagram showing a batch type ALD apparatus according to a second embodiment of the present invention.

Referring to FIG. 5, the batch type ALD apparatus includes: a reaction chamber 40 containing sidewalls 41C, an upper plate 41A, and a lower plate 41B; a radial shower head 42 penetrating a central area of the upper plate 41A of the reaction chamber 40 and radially injecting a source gas, a reaction gas, a purge gas, wherein the gases are supplied through a first and a second gas injection line 42A and 42B; a rotating axis 44 on which a plurality of wafers 46 are loaded in a radial form with an identical distance from a center of the rotating plate 45, wherein a center of bottom surface of the rotating plate 45 is fixed at the rotating axis 44; a baffle structured exhaust 47 for exhausting the gases injected from the radial shower head 42, the exhaust 47 penetrates the heating plate 43 and the lower plate 41B along the sidewall 41C most closely adjacent to an edge area of the rotating plate 45; a cooling plate 48 attached to the upper plate 41A; a plasma excitement electrode 49 having a ring shape and encompassing an entrance of the radial shower head 42 by being located between the cooling plate 48 and the entrance of the radial shower head 42; an ion extraction electrode 53 encompassing an discharging vent of the radial shower head 42 by being located between the upper plate 41A and the discharging vent of the radial shower head 42. Herein, the plasma excitement electrode is supplied with a radio frequency (RF) power; and an ion extraction electrode 53 encompassing discharging vent of the radial shower head 42 by being located between the upper plate 41A and the discharging vent of the radial shower head 42. Herein, the ion extraction electrode 53 is used for extracting Cl⁻ ions from Cl₂ molecules injected through a gas injection line 42B.

In conclusion, the plasma excitement electrode 49 and the ion extraction electrode 53 are aids for cleaning a remnant TiN layer, owing to a fact that both of the plasma excitement electrode 49 and the ion extraction electrode 53 ionize the Cl₂ molecules and the formed Cl⁻ ions are used for the cleaning process.

The radial shower head 42 or corn typed shower head improves uniformity of the deposition compared to the hole typed shower head, and the cooling plate 48 prevents the upper plate 41A from being deposited by any gas.

In addition, the heating plate 42 includes three heating zones, that is, a wafer heating area for depositing the atomic layer is divided into three heating zones Z₁, Z₂, Z₃. Each of the heating zones has an arrangement of a ring typed arc lamp 43A with a constant distance.

In more detail, the heating plate 43 is located right under the rotating plate 45. Among the three heating zones, a first heating zone Z₁ most closely adjacent to the radial shower head 42 has three arc lamps 43A. A third heating zone Z₃ most closely adjacent to an edge area of the rotating plate 45 has one arc lamp 43A, and a second heating zone Z₂ has two arc lamps is located between the first heating zone Z₁ and the third heating zone Z₃.

Accordingly, a temperature of each heating zone is varied by controlling a power rate of the arc lamps 43A. For example, the power rate of the arc lamp of the first heating zone (Z₁) is increased more than that of the arc lamp of the second heating zone Z₂ while the power rate of the arc lamp of the third heating zone Z₃ is decreased more than that of the arc lamp of the second heating zone Z₂. Contrarily, the power rate of the arc lamp 43A of the first heating zone Z₁ may be decreased while the power rate of the arc lamp 43A of the third heating zone Z₃ may be increased. Furthermore, the power rate of the arc lamp 43A is a parameter for deciding a deposition temperature of the wafer when an atomic layer is deposited on the wafer 46 and a setting temperature of the arc lamp is a target temperature at which the atomic layer is deposited on the wafer 46.

A groove 45A, commonly named as susceptor for loading and tightening the wafer 46 on the rotating plate 45 is prepared for preventing the atomic layer from being deposited on an underside of the wafer 46 and tightening the wafer 46 to prevent it from being shaken when the rotating plate 45 is rotated.

When the source gas, reaction gas, purge gas, and cleaning gas are supplied from the center of the upper plate 41A, that is, the radial shower head 42, a traveling wave flow of the supplied gas is formed in outward direction from the rotating plate 45, and eventually, the gases are pumped out from the reaction chamber 40 through the exhaust 47 of the rotating plate 45.

In addition, the rotating plate 45 is rotated so as to obtain enhanced deposition uniformity and load the wafer thereon, and an inert gas, that is, Ar gas, always flows along the bottom surface of the rotating plate 45 to prevent the atomic layer from being deposited thereon. At this time, the inert gas flowing along the bottom surface of the rotating plate 45 is supplied externally through an extra gas injection line even if not illustrated.

As mentioned above, uniformity of sheet resistance of a TiN layer is obtained through the followings: the gases are supplied from the center of the reaction chamber 40 through the radial shower head 42; a plurality of wafers are loaded on the rotating plate; and the wafer 46, on which the atomic layer is deposited, is divided into the three heating zones Z₁, Z₂ and Z₃ and each temperature of the three heating zones is controlled.

Instead of maintaining a temperature consistently throughout the whole region of the wafer 46, the heating plate 43 arranged with the ring type arc lamp 43A controls the power rate of each heating zone to be varied to have a different temperature distribution.

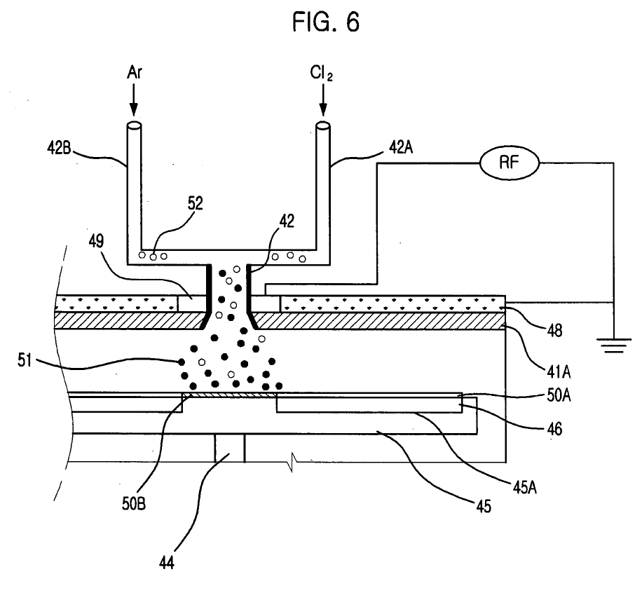

FIG. 6 is a diagram showing a method for an in-situ cleaning of the batch type ALD apparatus illustrated in FIG. 4.

Referring to FIG. 6, after depositing a TiN layer 50A on the wafer 46, a process for cleaning a remnant TiN layer 50B remaining on a central area of the rotating plate 45 is carried out.

First, cleaning gases are injected through the first and the second gas injection line 42A and 42B for injecting the source gas, reaction gas, and purge gas. Herein, the cleaning gas are Ar and Cl₂ and each of the cleaning gases is injected through each gas injection line separately. In more detail, the Ar gas is injected at a flow rate of about 500 sccm to about 1000 sccm while Cl₂ gas is injected at a flow rate of about 200 sccm to about 800 sccm. It is also possible to control each gas flow rate according to a stability condition of plasma.

After that, a RF power ranging from about 100 W to about 600 W and having a frequency of 13.56 MHz is applied to the plasma excitement electrode when the cleaning gases pass through the radial shower head 42 and a plasma state is created by the cleaning gases being excited at a pressure of about 1 torr to about 20 torr. Consequently, Cl₂ radicals, that is, the Cl₂ radicals mean activated Cl₂ molecules, are formed.

The activated Cl₂ molecules 51 are supplied in an radial form and intensively react with the remnant TiN layer 50B deposited on the central area of the rotating plate 45.

In other words, the reaction between the activated Cl₂ molecules 51 and the remnant TiN layer 50B is expedited by the activated Cl₂ molecules 51, and some by-products such as TiCl₄ and N₂ are generated by the reaction. Eventually, the by-products are pumped out without any difficulty because the by-products are easily detached from the center area of the rotating plate 45.

As mentioned above, the by-products are easily detached because the activated Cl₂ molecules 51 are injected in the radial form through the radial shower head 42 and the injected activated Cl₂ molecules are supplied broadly to the central area of the rotating plate 45 broadly and uniformly 42 during the cleaning process as shown in FIG. 6. In short, the generated by-products are easily detached because the activated Cl₂ molecules are not supplied intensively only to the central area of the rotating plate 45. Moreover, the above-described characteristic gas flow prevents the re-deposition phenomenon.

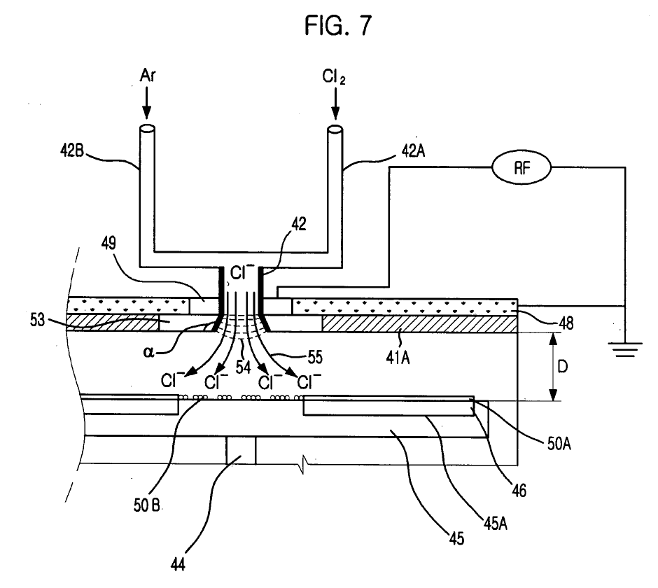

FIG. 7 is a diagram showing a method for the in-situ cleaning of the ALD apparatus illustrated in FIG. 5.

Referring to FIG. 7, the cleaning process for removing a remnant TiN layer 50B remaining on the central area of the rotating plate 45 is carried out after depositing the TiN layer 50A on the wafer 46.

First, the cleaning gas is injected through the first and second gas injection line 42A and 42B for injecting the source, reaction, and purge gas. At this time, Ar and Cl₂ are used as the cleaning gas, and injected through each gas injection line 42A and 42B separately. Specifically, the Ar gas and the Cl₂ gas are injected at a flow rate of about 500 sccm to about 1000 sccm and about 200 sccm to about 800 sccm respectively. It is also possible to control each flow rate according to a stability state of plasma.

Next, a large quantity of Cl⁻ ions are generated by applying a DC voltage, that is, ion extraction voltage, of about 500 V to about −50 V to the ion extraction electrode 53. Meanwhile, an electrical lens effect 54 occurs when the Cl⁻ ions, which are generated by the ion extraction electrode 53 located in the radial shower head 42, starts flowing, and an accelerated ion trajectory 55 of the Cl⁻ ions is formed by the electrical lens effect 54.

In short, the Cl⁻ ions are accelerated toward the rotating plate 45 along the accelerated ion trajectory 55 and the accelerated Cl⁻ ions remove the remnant TiN layer 50B easily. Herein, the removal of the TiN layer 50A is caused by a sputtering effect of the Cl⁻ ions.

Consequently, the in-situ cleaning method using the Cl₂ gas shows an improvement because both of a chemical etching and a physical, etching are carried out simultaneously. To obtain the sputtering effect mentioned above, in other words, to broaden a sputtering target area, an angle α of the exhaust 47 of the radial shower head 42 is increased and a distance d between the upper plate 41A and the rotating plate 45 is adjusted.

For example, an angle of about 120° to about 160° is most suitable for the exhaust 47 of the shower head 42, and a target area of the in-situ cleaning is adjusted by controlling the accelerated ion trajectory 55 of the Cl⁻ ions extracted by applying the DC voltage to the ion extraction electrode 52.

If the angle of the exhaust 47 of the shower head 42 is more than about 160°, the accelerated ion trajectory 55 of the extracted Cl⁻ ions becomes broad and the sputtering target area is also broadened. However, an efficiency on the in-situ cleaning is reduced because a density of the accelerated ions is decreased. In contrary, if the angle of the exhaust 47 of the shower head 42 becomes less than about 120°, the accelerated ion trajectory 55 of the extracted Cl⁻ ions becomes narrow and the sputtering target area also becomes narrow. However, the efficiency on the in-situ cleaning is also reduced because the sputtering target area is too narrow.

In addition, the distance D between the radial shower head 42 and the rotating plate 45 is kept up at about 3.5 mm to about 7 mm. In conclusion, the efficiency on the in-situ cleaning is considerably improved by adjusting the angle of the exhaust 47 of the radial shower head 42 and the distance D between the radial shower head 42 and the rotating plate 45 on condition that these adjustments do not affect properties of the TiN layer 50A such as sheet resistance Rs and thickness uniformity.

The above preferred embodiments describe the in-situ cleaning performed after finishing the TiN layer deposition. The present invention can be also applied to a case of depositing other material such as SiN, NbN, TiN, TaN, Ya₃N5, AlN, GaN, WN, BN, WBN, WSiN, TiSiN, TaSiN, AlSiN, AlTiN, Al₂O₃, TiO₂, HfO₂, Ta₂O₅, Nb₂O₅, CeO₂, Y₂0₃, SiO₂, In₂O₃, RuO₂, IrO₂, SrTiO₃, PbTiO₃, SrRuO₃, CaRuO₃, Al, Cu, Ti, Ta, Mo, Pt, Ru, Ir, W, or Ag, wherein such nitrides, metal oxide and metal mentioned above are applied to form a gate oxide layer, a gate electrode, an upper/lower electrode for a capacitor, a dielectric layer, a diffusion barrier layer, a metal wire and so on.

In addition, the batch type ALD deposition apparatus according to the present invention has a large volume of reaction chamber in which four 200 mm wafers can be loaded at once. In case of loading 300 mm wafer, it is possible to load three 300 mm wafers without changing any process parameter.

Although the preferred embodiment of the invention have been disclosed for illustrative purposes, those skilled in the art will appreciate that various modifications, additions and substitutions are possible, without departing from the scope and spirit of the invention as disclosed in the accompanying claims.

What is claimed is:

1. A batch type atomic layer deposition apparatus, comprising:
a reaction reaction chamber having a predetermined volume constituted with an upper plate, a lower plate and sidewalls;
a rotating plate loaded with a plurality of wafers, wherein each wafer is located in the reaction chamber and loaded radially at a predetermined position disposed in an identical distance from a center of the rotating plate;
a radial shower head for forcing a gas to flow toward an upper surface of the wafer as passing through a center of the upper plate, wherein the radial shower head faces a center of an upper surface of the rotating plate;
a heating plate having a heating zone capable of controlling a temperature of any area and being located on the lower plate with a predetermined distance of the rotating plate;
a cooling plate attached to an upper surface of the upper plate; and
a plasma excitement electrode encompassing an entrance of the radial shower head by being located between the cooling plate and the entrance of the radial shower head.

2. The batch type atomic deposition apparatus as recited in claim 1, further comprising an ion extraction electrode encompassing an exhaust of the radial shower head located between the exhaust of the radial shower head and the upper plate.

3. The batch type atomic deposition apparatus as recited in claim 2, wherein the ion extraction electrode is supplied with a DC voltage.

4. The batch type atomic deposition apparatus as recited in claim 1, wherein the plasma excitement electrode is constructed in a ring type structure and supplied with a RF power.

5. The batch type atomic deposition apparatus as recited in claim 1, wherein the exhaust of the radial shower head has an angle ranging from about 120° to about 160°.

6. The batch type atomic deposition apparatus as recited in claim 1, wherein a separating distance between the radial shower head and the rotating plate ranges from about 3.5 mm to about 7 mm.

7. A method for an in-situ cleaning of a batch type atomic layer deposition apparatus, the method comprising the steps of:
depositing an atomic layer on a wafer;
injecting a cleaning gas into a radial shower head;
applying a RF power to a plasma excitement electrode when the cleaning gas passes through the radial shower head; and
inducing a reaction between the cleaning gas activated by the plasma excitement electrode and a remnant atomic layer on a rotating plate.

8. The method as recited in claim 7, wherein the RF power of about 100 W to about 600 W is applied to the plasma excitement electrode.

9. The method as recited in claim 7, wherein the cleaning gas is a mixture of Cl₂ gas and Ar gas, however each gas is injected separately.

10. A method for an in-situ cleaning of a batch type atomic layer deposition apparatus, the method comprising the steps of:
depositing an atomic layer on a wafer;
injecting a cleaning gas into a radial shower head;
creating an activated molecule of a cleaning gas through applying a RF power to a plasma excitement electrode;
ionizing an activated molecule by applying an ion extraction voltage to an ion extraction electrode; and
inducing a collision between the ionized molecule and a remnant atomic layer of a rotating plate.

11. The method as recited in claim 10, wherein the ion extraction voltage applied to the ion extraction electrode ranges from about −500 V to about −50 V.

12. The method as recited in claim 10, wherein the RF power applied to the plasma excitement electrode ranges from about 100 W to about 600 W.

13. The method as recited in claim 10, wherein the cleaning gas is a mixture of Cl₂ gas and Ar gas, and each gas is injected separately.
